(19) United States
(12) Patent Application Publication
(10) Pub. No.: US 2010/0323471 A1
(43) Pub. Date: Dec. 23, 2010

(54) Selective Etch of Laser Scribed Solar Cell Substrate

(75) Inventors: Hien-Minh Huu Le, San Jose, CA (US); Tzay-Fa Su, San Jose, CA (US); David Tanner, San Jose, CA (US)

Correspondence Address: DIEHL SERVILLA LLC, 33 WOOD AVE SOUTH, SECOND FLOOR, SUITE 210, ISELIN, NJ, 08830, US

(73) Assignee: Applied Materials, Inc., Santa Clara, CA (US)

(21) Appl. No.: 12/195,946

(22) Filed: Aug. 21, 2008

(51) Int. Cl. H01L 31/0376

(52) U.S. Cl. 438/96; 257/E31.047

(57) ABSTRACT

Methods for making solar cells are described. The methods include selectively etching strips formed by laser scribing to remove oxides formed during laser scribing.

### TECHNICAL FIELD

Embodiments of the present invention generally relate to fabrication of photovoltaic cells. In particular, embodiments of the invention relate to methods of reducing contact resistance during the manufacture of solar cells.

### BACKGROUND

Photovoltaic (PV) or solar cells are material junction devices which convert sunlight into direct current (DC) electrical power. When exposed to sunlight (consisting of energy from photons), the electric field of solar cell p-n junctions separates pairs of free electrons and holes, thus generating a photo-voltage. A circuit from n-side to p-side allows the flow of electrons when the solar cell is connected to an electrical load, while the area and other parameters of the PV cell junction device determine the available current. Electrical power is the product of the voltage times the current generated as the electrons and holes recombine.

Solar cells have evolved significantly over the past two decades, with experimental efficiencies increasing from less than about 5% in 1980 to almost 40% in 2008. The most common solar cell material is silicon, which is in the form of single or polycrystalline wafers. Because the amortized cost of forming silicon-based solar cells to generate electricity is higher than the cost of generating electricity using traditional methods, there has been an effort to reduce the cost to form solar cells. In particular, thin-film techniques enable streamlined, high-volume manufacturing of solar cells and greatly reduced silicon consumption.

Thin-film solar devices typically consist of multiple thin layers of material deposited on sheet glass. Presently, a dominant solar cell thin-film is based on amorphous silicon (a-Si) in a so-called single junction configuration. Currently, solar cells and PV panels are manufactured by starting with many small silicon sheets or wafers as material units and processed into individual photovoltaic cells before they are assembled into PV modules and solar panels. These glass panels are typically subdivided into a large number (between 100 and 200) of individual solar cells by scribing processes that also define the electrical interconnects for adjacent cells. This scribing creates low-current active ‘strips,’ typically only 5-10 mm wide, which are electrically connected in series to produce high power (from tens of watts to a couple hundred watts, typically) with currents of a few amps. Laser scribing enables high-volume production of next-generation thin-film devices, and laser scribing outperforms mechanical scribing methods in quality, speed, and reliability.

Existing processes to produce solar panels using laser scribing can cause high contact resistance for the electrical connections, reducing cell performance of the solar panel. Therefore, there is a need for effective solar cell p-n junction formation to improve the fabrication process of solar cells.

### SUMMARY

Aspects of this invention involve methods for the manufacture of photovoltaic devices. In one embodiment, a method of making a photovoltaic device comprises depositing a transparent conductive oxide layer on a glass substrate; laser scribing a first strip through the entire transparent conductive layer thickness to provide a laser scribed transparent conductive oxide layer; depositing a silicon layer over the laser scribed transparent conductive oxide layer; laser scribing a second strip through the entire silicon layer thickness to provide as laser scribed silicon layer; depositing a metal layer over the laser scribed silicon layer; laser scribing a third strip through the entire metal layer and the entire transparent conductive oxide layer; and etching at least the second strip and the third strip to remove oxides of silicon.

The etching may involve a selective etching process, for example, by placing a mask adjacent the second and third strips. In one embodiment, the selective etching process is integrated with the laser scribing process. In one embodiment, the selective etching process is applied immediately after laser scribing the second strip and immediately after laser scribing the third strip.

In one embodiment, the method further comprises applying an AZO film to the silicon layer prior to laser scribing the second strip. In a specific embodiment, the method comprises applying an AZO film to the metal layer prior to laser scribing the third strip. In such embodiments, the method further comprises removing the AZO layer after etching the second strip. The method may further comprise removing the AZO layer after etching the third strip.

The silicon layer can comprise α silicon, for example, deposited using PECVD. The etching process according to one embodiment uses a carbon dioxide snow etching process.

In a specific embodiment, a method of making a photovoltaic cell comprises depositing a transparent conductive oxide layer on a glass substrate; laser scribing a first strip through the entire transparent conductive layer thickness to provide a laser scribed transparent conductive oxide layer; depositing an α silicon layer over the laser scribed transparent conductive oxide layer; laser scribing a second strip through the entire silicon layer thickness to provide as laser scribed silicon layer; selectively etching the second strip with an etchant that removes oxides of silicon from the second strip; depositing a metal layer over the laser scribed silicon layer; laser scribing a third strip through the entire metal layer and the entire transparent conductive oxide layer; and selectively etching the third strip to remove oxides of silicon from the third strip.

Another specific embodiment is directed to a method of making a photovoltaic cell comprising depositing a transparent conductive oxide layer on a glass substrate; laser scribing a first strip through the entire transparent conductive layer thickness to provide a laser scribed transparent conductive oxide layer; depositing an α silicon layer over the laser scribed transparent conductive oxide layer using a PECVD process; depositing an AZO blanket layer over the α silicon layer; laser scribing a second strip through the entire AZO layer and silicon layer thickness to provide as laser scribed silicon layer; etching the second strip with an etchant that removes oxides of silicon from the second strip; removing the AZO layer; depositing a metal layer over the laser scribed silicon layer; laser scribing a third strip through the entire metal layer and the entire transparent conductive oxide layer; and etching the third strip to remove oxides of silicon from the third strip.

### BRIEF DESCRIPTION OF THE DRAWINGS

FIG. 1 schematically illustrates a glass substrate coated with a transparent conductive oxide;

FIG. 2 shows the glass substrate of FIG. 1 after strips have been laser scribed through the transparent conductive oxide layer;

FIG. 3 show the glass substrate of FIG. 2 after a silicon layer has been deposited on the transparent conductive oxide layer;

FIG. 4 shows the glass substrate of FIG. 3 after the silicon layer has been laser scribed;

FIG. 5 shows the glass substrate of FIG. 4 after a metal layer has been deposited over the silicon layer; and

FIG. 6 shows the glass substrate of FIG. 5 after the metal layer and underlying transparent conductive oxide have been laser scribed.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the singular forms “a”, “an” and “the” include plural referents unless the context clearly indicates otherwise. It will be understood that the laser-scribing processes described herein are applicable to all types of thin-film solar cell manufacturing, including those based on CdTe (cadmium telluride) and cigs (copper indium gallium selenide).

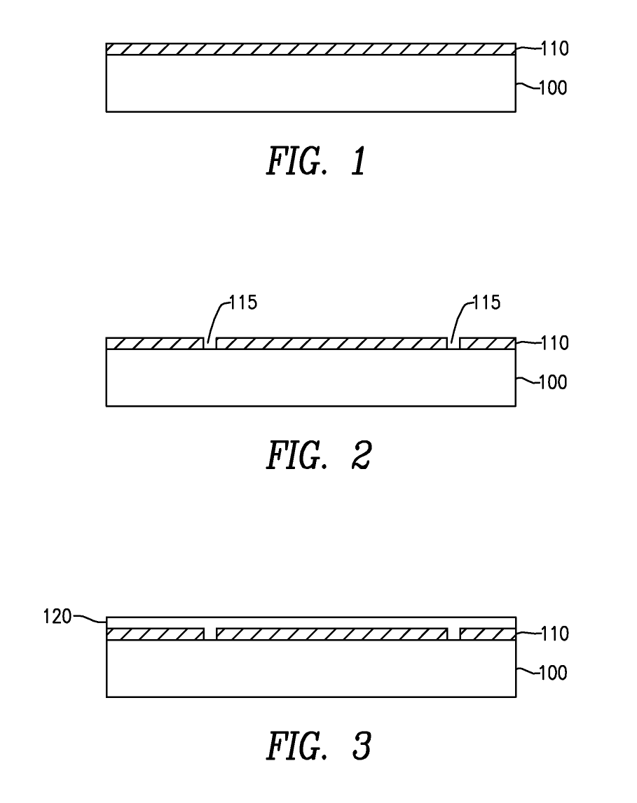

Referring to FIGS. 1-6 an exemplary embodiment of a manufacturing process for solar cells is shown. Starting at FIG. 1, solar cells are manufactured by starting with a glass sheet or substrate 100. An exemplary thickness for the glass sheet is about 3 mm. In the art, this glass substrate actually is called a glass superstrate, because sunlight will enter through this support glass. During the manufacture of a solar cell, first a continuous, uniform layer of TCO (transparent conductive oxide) 110 is deposited on the glass substrate 100. The thickness of the TCO layer 110 is typically a few hundred nanometers. The TCO layer eventually forms the front electrodes of the solar cell. Suitable materials for the TCO layer include AZO or tin oxide (SNO₂), and the TCO layer can be deposited by any suitable process such as chemical vapor deposition or sputtering.

Referring now to FIG. 2, after deposition of the TCO layer, this is followed by a laser scribing process, which is often referred to as P1, which scribes strips 115 through the entire TCO layer thickness. As shown in FIG. 3, after this first scribing process P1, a p- and n-type silicon layer 120 is deposited over the TCO layer, and the silicon layer, which is typically α silicon. The total thickness of the silicon layer is typically on the order of 0.5-3 μm, and this layer is usually deposited by chemical vapor deposition or other suitable processes.

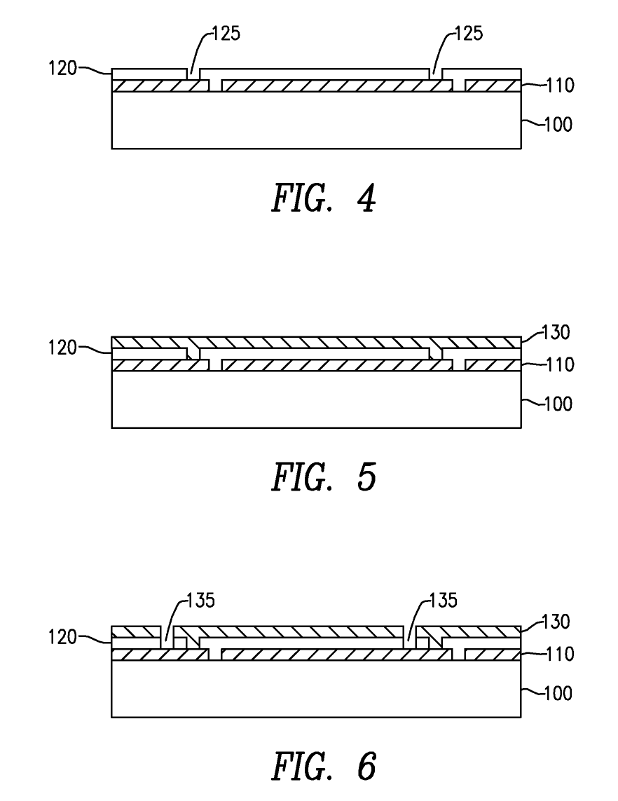

Referring to FIG. 4, the silicon deposition step is followed by a second laser scribing step, often referred to as P2, which completely cuts strips 125 through the silicon layer 120. As shown in FIG. 5, a metal layer 130 that forms the rear electrodes is deposited over the silicon layer 120. The metal layer may be any suitable metals such as aluminum, silver, or molybdenum, and this layer can be deposited by a suitable deposition process such as physical vapor deposition. Referring now to FIG. 6, a third scribe process, called P3, is used to scribe strips 135 through the metal layer 130 and the silicon layer 120. The panel is then sealed with a rear surface glass lamination.

The deposition of the various layers can be performed in a vacuum deposition chamber. The vacuum deposition chamber can be a stand-alone chamber or as part of a sheet processing system. In some cases, the vacuum deposition chamber may be part of a multi-chamber system. The glass substrate 100 can be a glass sheet suitable for solar cell fabrication is used. A sheet size of about 50 mm×50 mm or larger can be used. Typical sheet size for solar cell fabrication may be about 100 mm×100 mm or larger, such as about 156 mm.times.156 mm or larger in size; however, smaller or larger sizes/dimensions can also be used to advantage, e.g., a size of about 400 mm×500 mm can also be used. The thickness of a solar cell sheet may, for example, be a few hundred microns, such as between about 100 microns to about 350 microns. Each sheet may be suitable for forming a single p-n junction, a dual junction, a triple junction, tunnel junction, p-i-n junction, or any other types of p-n junctions created by suitable semiconductor materials for solar cell manufacturing. In another embodiment, at least a surface of the sheet may include p-type silicon material thereon.

The laser scribing processes P1, P2 and P3 can be carried out with any suitable laser scribing tool. Scribe lines are currently on the order of several tens of microns in width. The P1 scribe process typically uses lasers with up to 8 W of near-IR, and the P2 and P3 processes typically only need a few hundred milliwatts of green output. An example of a suitable laser operates a frequency of 20 kHz (+/−2 KHz) and a current of 17 A (+/−2 A).

According to the present invention, after the laser scribing P2 and P3, etching is used to remove oxides of silicon that may form during or after the laser scribing process. A variety of etching processes can be used, but it is desired that the etching is performed in the process chamber immediately after laser scribing. Therefore, an in situ etching process such as selective etching or an etching process that is applied locally to the scribed strip area is preferred. As is understood in the art of semiconductor processing, selective etching involves applying a mask over the area surrounding the area to be etched. Thus, for example, with reference to FIG. 4, a mask resistant to the etch chemistry would be applied over layer 120, leaving an opening over the scribe strips 125. Thereafter, the scribe strips 125 would be etched by a suitable etching process, for example etching with chlorine, fluorine, HCl, evaporative carbon dioxide or snow carbon dioxide. Other suitable etching chemistries or processes can be used. It will be understood that selective etching can be used to etch the scribe strips 135 shown in FIG. 6.

Another suitable etching process may involve non-selective etching. An AZO or other layer can be applied over layer 120 shown in FIG. 3 prior to etching. Then, the laser scribing process can be used to etch through the AZO layer and the underlying layer 120. Thereafter, the scribed strips 125 can be etched with a suitable etching technique. It will be understood that both etching steps can be the same type of etching technique, for example, selective or non-selective, or different types of etching techniques can be used in conjunction with the scribe processes P2 and P3.

In specific embodiments, the etch process is integrated with the laser process such that the etching is performed in situ immediately after scribing. This can be performed in a load locked chamber to prevent exposure of the scribed surface to ambient atmosphere, which minimizes the formation of oxides of silicon. Removal of such oxides establishes better back contact. Suitable etchants include hydrofluoric acid. A low concentration (e.g., 20-50% concentration) can be used as an etchant to remove any oxide formed during the process.

After the solar cell is formed as described above, the cell may be heat treated by annealing. In addition, the sheet may be subjected to a variety of wiring schemes and/or surface treatment steps.

A suitable vacuum deposition chamber may include various chemical vapor deposition chambers. As noted above, the silicon layer is deposited by plasma enhanced chemical vapor deposition (PECVD). The PECVD system may be configured to process various types of sheets, such as various parallel-plate radio-frequency (RF) plasma enhanced chemical vapor deposition (PECVD) systems for various sheet sizes, available from AKT, a division of Applied Materials, Inc., Santa Clara, Calif. However, it should be understood that the invention has utility in other system configurations, such as other chemical vapor deposition systems and any other film deposition systems.

For solar cell fabrication, additional layers can be deposited on the sheet. For example, one or more passivation layers or anti-reflective coating layers can be deposited on the front and/or back side of the sheet.

Although the invention herein has been described with reference to particular embodiments, it is to be understood that these embodiments are merely illustrative of the principles and applications of the present invention. The CVD process herein can be carried out using other CVD chambers, adjusting the gas flow rates, pressure, plasma density, and temperature so as to obtain high quality films at practical deposition rates. It is understood that embodiments of the invention include scaling up or scaling down any of the process parameter/variables as described herein according to sheet sizes, chamber conditions, etc., among others. It will be apparent to those skilled in the art that various modifications and variations can be made to the method and method of the present invention without departing from the spirit and scope of the invention. Thus, it is intended that the present invention include modifications and variations that are within the scope of the appended claims and their equivalents.

What is claimed is:

1. A method of making a photovoltaic device comprising:
depositing a transparent conductive oxide layer on a glass substrate;
laser scribing a first strip through the entire transparent conductive layer thickness to provide a laser scribed transparent conductive oxide layer;
depositing a silicon layer over the laser scribed transparent conductive oxide layer;
laser scribing a second strip through the entire silicon layer thickness to provide as laser scribed silicon layer;
depositing a metal layer over the laser scribed silicon layer;
laser scribing a third strip through the entire metal layer and the entire transparent conductive oxide layer; and
etching at least the second strip and the third strip to remove oxides of silicon.

2. The method of claim 1, wherein the etching includes a selective etching process.

3. The method of claim 2, further comprising a placing a mask adjacent the second and third strips.

4. The method of claim 3, wherein the selective etching process is integrated with the laser scribing process.

5. The method of claim 4, wherein the selective etching process is applied immediately after laser scribing the second strip and immediately after laser scribing the third strip.

6. The method of claim 1, further comprising applying an AZO film to the silicon layer prior to laser scribing the second strip.

7. The method of claim 7, further comprising applying an AZO film to the metal layer prior to laser scribing the third strip.

8. The method of claim 6, further comprising removing the AZO layer after etching the second strip.

9. The method of claim 7, further comprising removing the AZO layer after etching the third strip.

10. The method of claim 1, wherein the silicon layer comprises α silicon.

11. The method of claim 10, wherein the α silicon is deposited using PECVD.

12. The method of claim 1, wherein the etching process uses a carbon dioxide snow etching process.

13. A method of making a photovoltaic cell comprising:
depositing a transparent conductive oxide layer on a glass substrate;
laser scribing a first strip through the entire transparent conductive layer thickness to provide a laser scribed transparent conductive oxide layer;
depositing an α silicon layer over the laser scribed transparent conductive oxide layer;
laser scribing a second strip through the entire silicon layer thickness to provide as laser scribed silicon layer;
selectively etching the second strip with an etchant that removes oxides of silicon from the second strip;
depositing a metal layer over the laser scribed silicon layer;
laser scribing a third strip through the entire metal layer and the entire transparent conductive oxide layer; and
selectively etching the third strip to remove oxides of silicon from the third strip.

14. The method of claim 13, the etching is performed immediately after laser scribing the second strip and immediately after laser scribing the second strip.

15. The method of claim 12, wherein etchant is selected from chlorine, fluorine, HCl, evaporative carbon dioxide and carbon dioxide snow.

16. A method of making a photovoltaic cell comprising
depositing a transparent conductive oxide layer on a glass substrate;
laser scribing a first strip through the entire transparent conductive layer thickness to provide a laser scribed transparent conductive oxide layer;
depositing an α silicon layer over the laser scribed transparent conductive oxide layer using a PECVD process;
depositing an AZO blanket layer over the α silicon layer;
laser scribing a second strip through the entire AZO layer and silicon layer thickness to provide as laser scribed silicon layer;
etching the second strip with an etchant that removes oxides of silicon from the second strip; removing the AZO layer;
depositing a metal layer over the laser scribed silicon layer;
laser scribing a third strip through the entire metal layer and the entire transparent conductive oxide layer; and
etching the third strip to remove oxides of silicon from the third strip.

17. The method of claim 16, further comprising applying a second AZO layer over the metal layer and removing the AZO layer after etching the third strip.
